(19) United States
(12) Patent Application Publication
(10) Pub. No.: US 2026/0353918 A1
(43) Pub. Date: Nov. 5, 2026

(54) LIGHT-EMITTING ELEMENT

(71) Applicant: TAIZHOU GUANYU TECHNOLOGY CO., LTD., ZHEJIANG PROVINCE (CN)

(72) Inventors: HSUPING CHEN, TAINAN CITY (TW); KUO-CHENG HSU, TAICHUNG CITY (TW); QIONG DING, ZHEJIANG PROVINCE (CN)

(21) Appl. No.: 19/655,757

(22) Filed: Apr. 23, 2026

(30) Foreign Application Priority Data
Apr. 30, 2025 (CN) 202510572492.X

(51) Int. Cl. H10K 50/86; H10K 50/813; H10K 50/822

(52) U.S. Cl. CPC H10K 50/865; H10K 50/813; H10K 50/822

(57) ABSTRACT

A light-emitting element includes a substrate, a plurality of light-shielding layers, a plurality of first electrode layers, a light-emitting layer, and a second electrode layer. The plurality of light-shielding layers are disposed at intervals on a first surface of the substrate; the plurality of first electrode layers are disposed on the first surface of the substrate, each of the plurality of first electrode layers is disposed between the two adjacent light-shielding layers; the light-emitting layer covers the plurality of first electrode layers; and the second electrode layer covers the light-emitting layer.

### PRIORITY CLAIM AND CROSS-REFERENCE

This application claims the benefit of China patent application No. 202510572492.X, filed on Apr. 30, 2025, the entirety of which are incorporated by reference herein.

### BACKGROUND OF THE DISCLOSURE

### Field of the Disclosure

The present disclosure relates to a light-emitting element, and more particularly to an organic light-emitting element.

### Description of the Prior Art

Organic light-emitting displays have been widely used in most high-end electronic devices. However, due to the limitations of existing technology, the luminous efficiency and quality of light-emitting materials cannot be effectively controlled, resulting in the optical performance of the devices being below expectations.

### SUMMARY OF THE DISCLOSURE

In the present disclosure, a light-emitting element comprises a substrate, a plurality of light-shielding layers, a plurality of first electrode layers, a light-emitting layer, and a second electrode layer. The plurality of light-shielding layers are disposed at intervals over a first surface of the substrate; the plurality of first electrode layers are disposed over the first surface of the substrate, each of the plurality of first electrode layers is disposed between the two adjacent light-shielding layers; the light-emitting layer covers the plurality of first electrode layers; and the second electrode layer covers the light-emitting layer.

In the present disclosure, a method of manufacturing a light-emitting element comprises: providing a substrate; forming a plurality of light-shielding layers at intervals over a first surface of the substrate; forming a plurality of first electrode layers over the substrate, including forming a central portion between the light-shielding layers and an end portion extending from a side of the central portion and disposed across a sidewall and a part of a top surface of the adjacent light-shielding layer; forming a light-emitting layer over the plurality of first electrode layers; and forming a second electrode layer over the light-emitting layer.

In some embodiments, each of the plurality of first electrode layers includes a central portion and an end portion extending from a side of the central portion, the central portion is disposed between the two adjacent light-shielding layers, and the end portion is disposed across a sidewall and a part of a top surface of the adjacent light-shielding layer.

In some embodiments, an angle between a sidewall of the end portion of the first electrode layer and the top surface of the light-shielding layer is greater than 0 degree and up to about 90 degrees.

In some embodiments, a thickness of the central portion of the first electrode layer is substantially equal to or less than a thickness of the light-shielding layer.

In some embodiments, the light-emitting element further comprises a plurality of bumps arranged over the plurality of light-shielding layers, and the light-emitting layer covering the plurality of bumps.

In some embodiments, the light-emitting element further comprises a plurality of bumps arranged over the plurality of light-shielding layers, the plurality of bumps partially covering the end portion of the first electrode layer, and the light-emitting layer covering the plurality of bumps.

In some embodiments, a thickness of the central portion of the first electrode layer is substantially equal to a thickness of the end portion.

In some embodiments, a width of a top surface of each of the plurality of light-shielding layers is substantially equal to or less than a width of a bottom portion thereof.

In some embodiments, an angle between a sidewall of each of the plurality of light-shielding layers and the first surface of the substrate is greater than 0 degree and up to about 90 degrees.

In some embodiments, the plurality of light-shielding layers includes a light-absorbing layer disposed over the first surface of the substrate and a bonding layer covering the light-absorbing layer.

In some embodiments, prior to forming the light-emitting layer, a plurality of bumps are formed over the plurality of light-shielding layers and partially cover the end portion of the first electrode layer; the light-emitting layer is formed over the plurality of first electrode layers and the plurality of light-shielding layers.

### BRIEF DESCRIPTION OF THE DRAWINGS

FIG. 1 is a top view illustrating an intermediate product of a light-emitting element.

FIG. 2 is a cross-sectional view along a line A-A' in FIG. 1.

FIG. 3 is a partial cross-sectional view along the line AA in FIG. 1.

FIG. 4 is a partial cross-sectional view along the line AA in FIG. 1.

FIG. 5 is a partial cross-sectional view along the line AA in FIG. 1.

FIG. 6 is a partial cross-sectional view along the line AA in FIG. 1.

FIG. 7 is a partial cross-sectional view along the line AA in FIG. 1.

FIG. 8 is a partial cross-sectional view along the line AA in FIG. 1.

FIGS. 9A-9D illustrate different stages of a manufacturing process of a light-emitting element according to an embodiment.

### DETAILED DESCRIPTION OF THE EMBODIMENTS

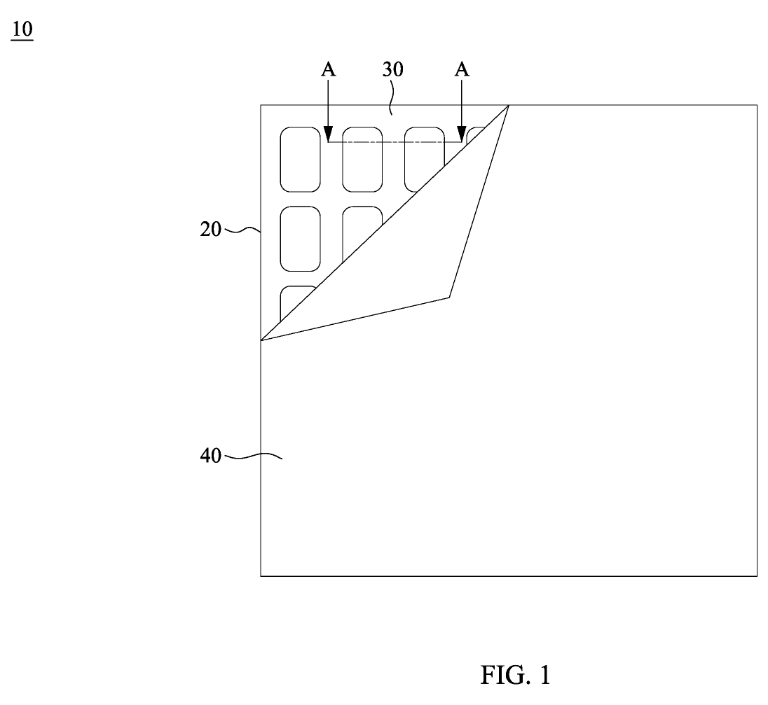

FIG. 1 is a top view illustrating an intermediate product of a light-emitting element 10. The light-emitting element 10 comprises a light-emitting layer 20 and an overlying layer 40 located over the light-emitting layer 20. For the light-emitting layer 20, spacers 21 may be designed to provide an array of recesses for accommodating a light-emitting pixel array. In some embodiments, the spacers 21 may include a photosensitive material.

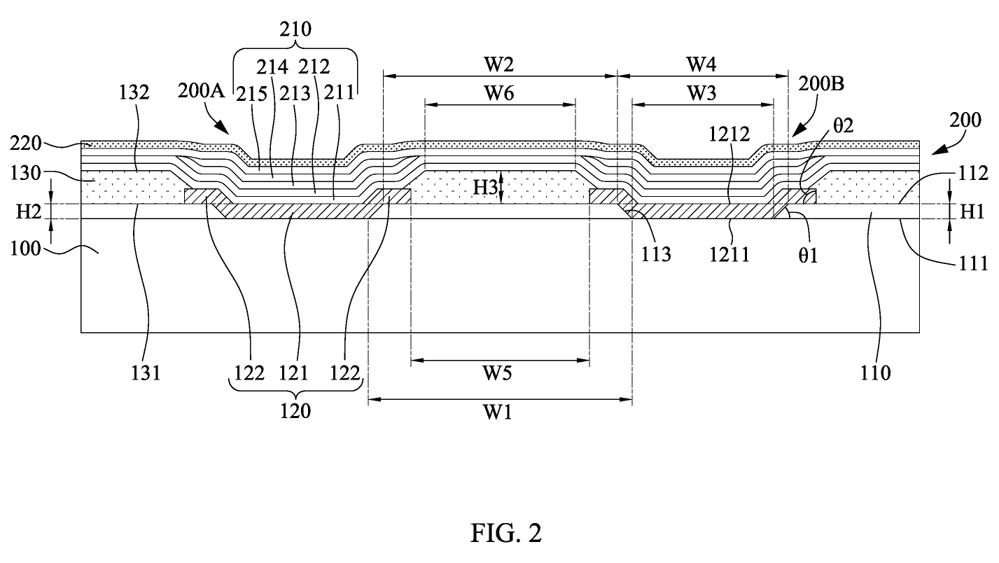

FIG. 2 is a cross-sectional view along a line AA in FIG. 1 and illustrates only a light-emitting region. For simplicity, the overlying layer 40 is omitted here. In some embodiments, the light-emitting element 10 comprises a substrate 100, a plurality of light-shielding layers 110 over the substrate 100, a plurality of first electrode layers 120, a plurality of bumps 130, and a light-emitting array 200.

In some embodiments, the substrate 100 may comprise a thin-film transistor (TFT) array configured to correspond to light-emitting pixels in the light-emitting layer 20. The substrate 100 may include several capacitors. In some embodiments, more than one transistor is configured to form a circuit together with one capacitor and one light-emitting pixel.

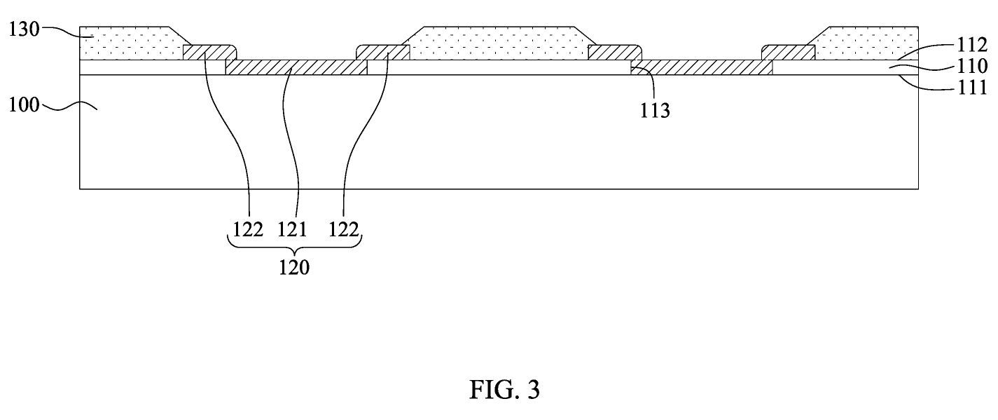

In some embodiments, the light-shielding layers 110 are disposed at intervals on a first surface of the substrate 100. In the present disclosure, the pattern of the light-shielding layers 110 is designed according to the pixel arrangement, and the patterned light-shielding layers 110 may be referred to as a pixel defined layer (PDL). The light-shielding layer 110 comprises a bottom surface 111, a top surface 112, and a sidewall 113. The bottom surface 111 of the light-shielding layer 110 is in direct contact with the first surface of the substrate 100. A thickness H1 is defined between the top surface 112 and the bottom surface 111 of the light-shielding layer 110. A width W1 of the bottom surface of the light-shielding layer 110 is substantially equal to or greater than a width W2 of the top surface 112 of the light-shielding layer 110. In some embodiments, the width W1 of the bottom surface 111 of the light-shielding layer 110 is substantially equal to the width W2 of the top surface 112 of the light-shielding layer 110. The light-shielding layer 110 has a rectangular cross-section, as shown in FIGS. 3, 5, and 7. In some embodiments, the width W1 of the bottom surface 111 of the light-shielding layer 110 is greater than the width W2 of the top surface 112 of the light-shielding layer 110. The light-shielding layer 110 has a trapezoidal cross-section, as shown in FIGS. 2, 4, and 6. In some embodiments, a ratio of the width W1 of the bottom surface 111 of the light-shielding layer 110 to the width W2 of the top surface 112 of the light-shielding layer 110 is about 10:1 to about 1:1. In some embodiments, the ratio of the width W1 of the bottom surface 111 of the light-shielding layer 110 to the width W2 of the top surface 112 of the light-shielding layer 110 is about 7:1 to about 1:1. In some embodiments, the ratio of the width W1 of the bottom surface 111 of the light-shielding layer 110 to the width W2 of the top surface 112 of the light-shielding layer 110 is about 3:1 to about 1:1.

In some embodiments, an angle θ1 between the sidewall 113 of the light-shielding layer 110 and the first surface of the substrate 100 is greater than 0 degree and up to about 90 degrees. In some embodiments, the angle θ1 between the sidewall 113 of the light-shielding layer 110 and the first surface of the substrate 100 is about 20 degrees to about 70 degrees. In some embodiments, the angle θ1 between the sidewall 113 of the light-shielding layer 110 and the first surface of the substrate 100 is about 35 degrees to about 60 degrees.

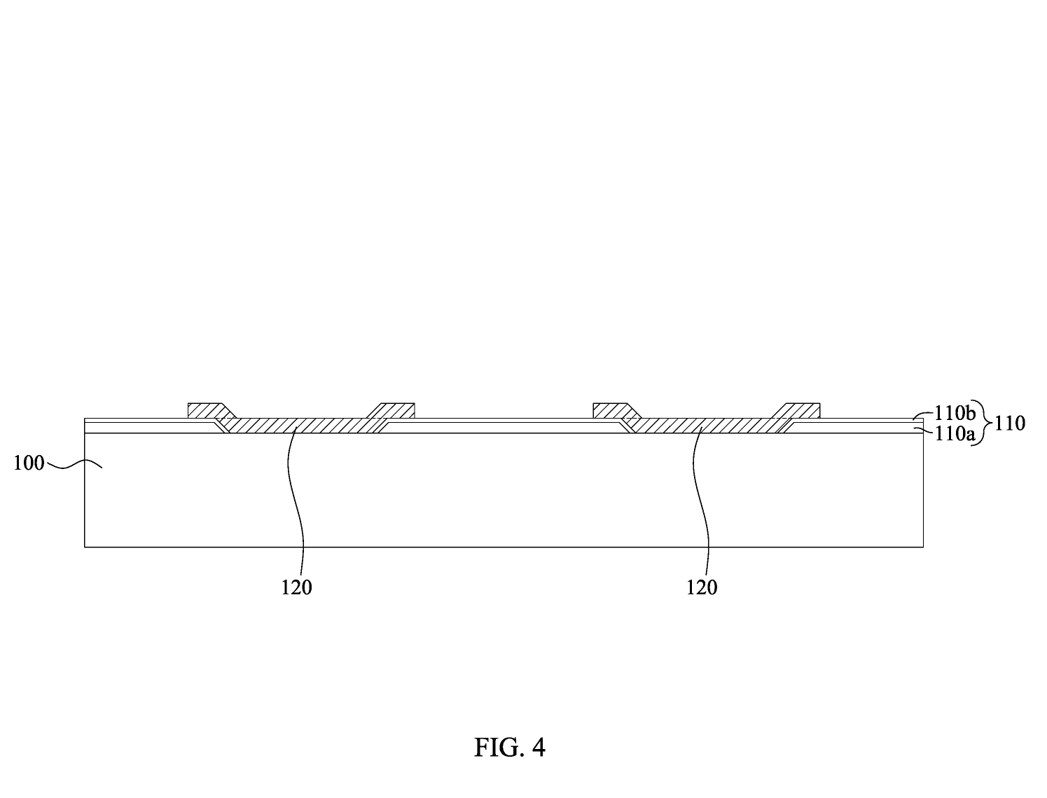

In some embodiments, the light-shielding layer 110 includes a light-absorbing material, including but not limited to metal, metal oxide, carbon black materials, such as carbon black nanoparticles, conductive fibers including carbon black, or the like. In some embodiments, the light-shielding layer 110 comprises a blackbody material having an absorption rate of 90%, 95%, 99%, 99.5%, or 99.9% or more for visible light. The light-shielding layer 110 may include a single material layer or a plurality of different material layers. In some embodiments, the light-shielding layer 110 includes a single metal layer. In some embodiments, the light-shielding layer 110 includes a single metal oxide layer. In some embodiments, the light-shielding layer 110 includes one or more metal layers and one or more metal oxide layers. In some embodiments, the light-shielding layer 110 further includes a bonding layer, such as a silicon dioxide layer. In some embodiments, as shown in FIG. 4, the light-shielding layer 110 includes a light-absorbing layer 110a and a bonding layer 110b covering the light-absorbing layer 110a as a top layer. In some embodiments, the bonding layer 110b comprises a material that is the same as or compatible with a material of the bumps 130 subsequently formed thereon, such as a silicon dioxide layer, so that the light-shielding layer 110 can have better adhesion to the bumps 130 formed thereon later. In some embodiments, the single layer or multiple layers in the light-shielding layer 110 may be formed by any of vapor deposition, sputtering, atomic layer deposition, thermal evaporation, coating, or spraying.

A plurality of first electrode layers 120 are disposed on the first surface of the substrate 100, each of the plurality of first electrode layers 120 includes a central portion 121 formed between the light-shielding layers 110 and an end portion 122 extending from opposite sides of the central portion 121. In some embodiments, a shape of the central portion 121 of the first electrode layer 120 may vary according to a shape of the sidewall 113 of the light-shielding layer 110. In some embodiments, a width W3 of a bottom surface 111 of the central portion 121 of the first electrode layer 120 is substantially equal to or less than a width W4 of a top surface 1212 of the central portion 121 of the first electrode layer 120. In some embodiments, a ratio of the width W3 of the bottom surface 111 of the central portion 121 of the first electrode layer 120 to the width W4 of the top surface 1212 of the central portion 121 of the first electrode layer 120 is about 1:7 to about 1:1. In some embodiments, the ratio of the width W3 of the bottom surface 111 of the central portion 121 of the first electrode layer 120 to the width W4 of the top surface 1212 of the central portion 121 of the first electrode layer 120 is about 1:3 to about 1:1. In some embodiments, as shown in FIGS. 2, 4, and 6, the width W1 of the bottom surface 111 of the light-shielding layer 110 is less than the width W2 of the top surface 112 of the light-shielding layer 110, the light-shielding layer 110 has a trapezoidal cross-section, and the central portion 121 of the first electrode layer 120 has an inverted trapezoidal cross-section. In some embodiments, as shown in FIGS. 3, 5, and 7, the width W1 of the bottom surface 111 of the light-shielding layer 110 is substantially equal to the width W2 of the top surface 112 of the light-shielding layer 110, the light-shielding layer 110 has a rectangular cross-section, and the central portion 121 of the first electrode layer 120 has a rectangular cross-section.

In some embodiments, the width W3 of the bottom surface 111 of the central portion 121 of the first electrode layer 120 is substantially equal to, greater than, or less than the width W1 of the bottom surface 111 of the light-shielding layer 110. In some embodiments, the width W3 of the bottom surface 111 of the central portion 121 of the first electrode layer 120 is less than the width W1 of the bottom surface 111 of the light-shielding layer 110. In some embodiments, a ratio of the width W3 of the bottom surface 111 of the central portion 121 of the first electrode layer 120 to the width W1 of the bottom surface 111 of the light-shielding layer 110 is about 1:1 to about 1:10. In some embodiments, the ratio of the width W3 of the bottom surface 111 of the central portion 121 of the first electrode layer 120 to the width W1 of the bottom surface 111 of the light-shielding layer 110 is about 1:2 to about 1:8. In some embodiments, the ratio of the width W3 of the bottom surface 111 of the central portion 121 of the first electrode layer 120 to the width W1 of the bottom surface 111 of the light-shielding layer 110 is about 1:3 to about 1:5.

In some embodiments, the width W4 of the top surface 1212 of the central portion 121 of the first electrode layer 120 is substantially equal to, greater than, or less than the width W1 of the bottom surface 111 of the light-shielding layer 110. In some embodiments, the width W4 of the top surface 1212 of the central portion 121 of the first electrode layer 120 is substantially greater than the width W1 of the bottom surface 111 of the light-shielding layer 110. In some embodiments, a ratio of the width W4 of the top surface 1212 of the central portion 121 of the first electrode layer 120 to the width W1 of the bottom surface 111 of the light-shielding layer 110 is about 1:1 to about 1:10. In some embodiments, the ratio of the width W4 of the top surface 1212 of the central portion 121 of the first electrode layer 120 to the width W1 of the bottom surface 111 of the light-shielding layer 110 is about 1:2 to about 1:8. In some embodiments, the ratio of the width W4 of the top surface 1212 of the central portion 121 of the first electrode layer 120 to the width W1 of the bottom surface 111 of the light-shielding layer 110 is about 1:3 to about 1:5.

In some embodiments, a thickness H2 of the central portion 121 of the first electrode layer 120 is substantially equal to, less than, or greater than the thickness H1 of the light-shielding layer 110. In some embodiments, the thickness H2 of the central portion 121 of the first electrode layer 120 is substantially equal to or less than the thickness H1 of the light-shielding layer 110. In some embodiments, a ratio of the thickness H2 of the central portion 121 of the first electrode layer 120 to the thickness H1 of the light-shielding layer 110 is about 3:1 to about 1:3. In some embodiments, the ratio of the thickness H2 of the central portion 121 of the first electrode layer 120 to the thickness H1 of the light-shielding layer 110 is about 2:1 to about 1:2.

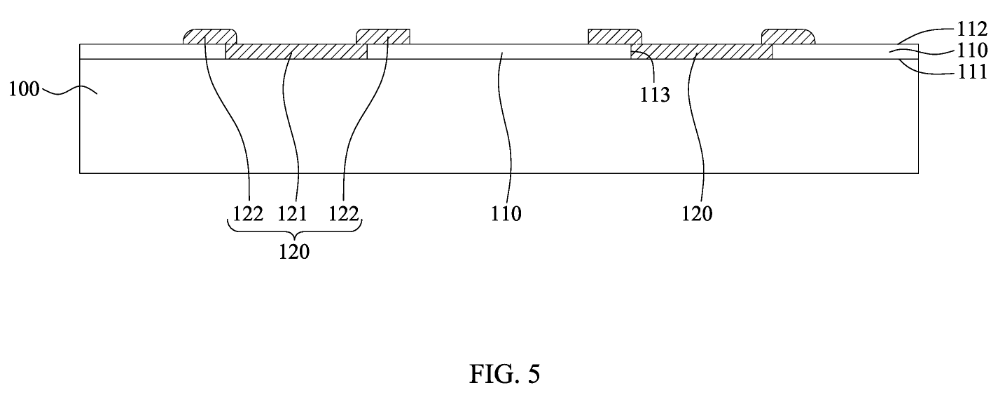

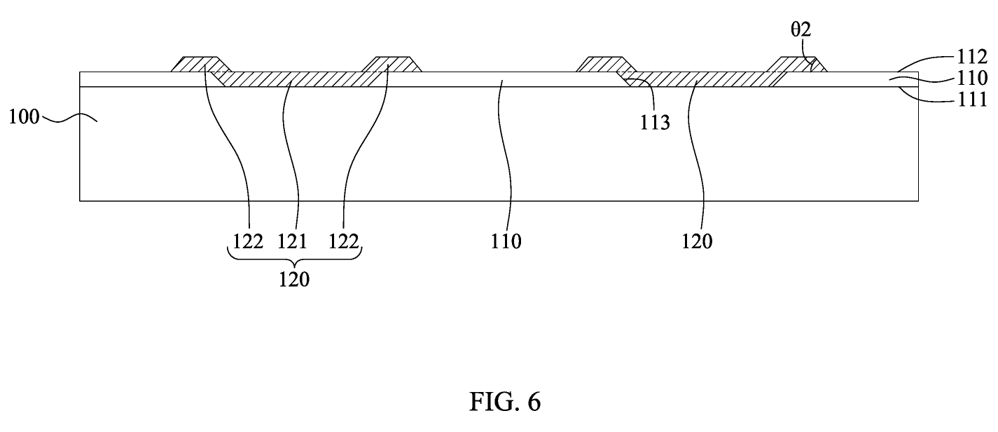

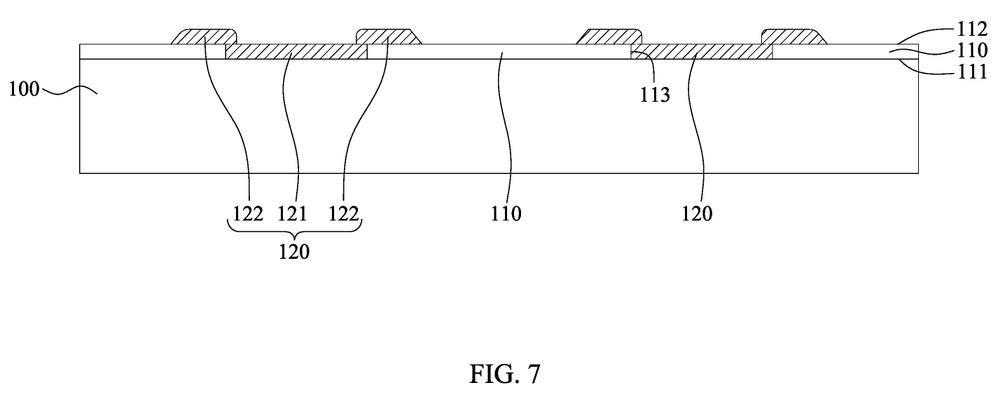

In some embodiments, the end portion 122 of the first electrode layer 120 is disposed across the sidewall 113 and part of the top surface 112 of the adjacent light-shielding layer 110, and an angle θ2 between a sidewall of the end portion 122 of the first electrode layer 120 and the top surface 112 of the light-shielding layer 110 is greater than 0 degree and up to about 90 degrees. In some embodiments, the angle θ2 between the sidewall of the end portion 122 of the first electrode layer 120 and the top surface 112 of the light-shielding layer 110 is greater than 20 degrees and up to about 70 degrees. In some embodiments, the angle θ2 between the sidewall of the end portion 122 of the first electrode layer 120 and the top surface 112 of the light-shielding layer 110 is greater than 35 degrees and up to about 60 degrees. In some embodiments, as shown in FIGS. 2-5, the angle θ2 between the sidewall of the end portion 122 of the first electrode layer 120 and the top surface 112 of the light-shielding layer 110 is about 90 degrees. In some embodiments, as shown in FIGS. 6 and 7, the angle θ2 between the sidewall of the end portion 122 of the first electrode layer 120 and the top surface 112 of the light-shielding layer 110 is less than 90 degrees. In some embodiments, as shown in FIGS. 5 and 7, a corner between the sidewall and the top surface at the end portion 122 of the first electrode layer 120 may be arc-shaped. In some embodiments, the light-emitting assembly 10 may include a plurality of bumps 130 covering the respective end portions 122 of the first electrode layer 120, so as to ensure that the first electrode layer 120 is not in direct contact with the second electrode layer 220. In some embodiments, the light-emitting assembly 10 may not include bumps 130, or may partially include bumps 130; therefore, the corner between the sidewall and the top surface at the end portion 122 of the first electrode layer 120 is arc-shaped, which can prevent the corner between the sidewall and the top surface of the first electrode layer 120 from piercing an organic layer 210 of the organic light-emitting array 200, thereby ensuring that the first electrode layer 120 is not in direct contact with the second electrode layer 220. In some embodiments, the thickness of the central portion 121 of the first electrode layer 120 is substantially equal to a thickness of the end portion 122.

In some embodiments, the first electrode layer 120 may include ITO, IZO, IGZO, AlCu alloy, AgMo alloy, ITO (or IZO or IGZO) with a thickness of about 50 Å to about 500 Å and a metal film (Ag, Al, Mg, Au) with a thickness of about 500 Å to about 2000 Å, and ITO (or IZO or IGZO) with a thickness of about 50 Å to about 1000 Å. In some embodiments, the first electrode layer 120 is a composite structure. For example, the first electrode layer 120 comprises a conductive film and a transparent conductive film thereon. The conductive film is located between the transparent conductive film and the substrate 100. In some embodiments, the conductive film includes aluminum, gold, silver, copper, etc. In some embodiments, the transparent conductive film includes indium, tin, graphene, zinc, oxygen, etc. In some embodiments, the first electrode layer 120 comprises a transparent conductive thin film. In some embodiments, the first electrode layer 120 comprises ITO (indium tin oxide). In some embodiments, the first electrode layer 120 comprises IZO (indium zinc oxide). In some embodiments, the first electrode layer 120 comprises IGZO (indium gallium zinc oxide). In some embodiments, a roughness Ra of the transparent conductive film is less than 10 Å. A thickness of the conductive film may be between about 1500 Å and about 3000 Å. A thickness of the transparent conductive film may be between about 80 Å and about 1000 Å.

In some embodiments, the first electrode layer 120 comprises at least three different films. The conductive film (e.g., Al, Cu, Ag, Au, etc.) is sandwiched between two transparent conductive films. In some cases, one of the two transparent conductive films is ITO, with one side in contact with the substrate 100 and the other side in contact with the conductive film. In some cases, one of the two transparent conductive films is ITO, with one side in contact with the conductive film and the other side in contact with the bump 130 or the light-emitting array 200.

In some embodiments, each bump 130 is arranged on the light-shielding layer 110, protruding away from the substrate 100 and covering a peripheral region of the first electrode layer 120. In some embodiments, positions of the plurality of bumps 130 may correspond one-to-one with positions of the plurality of light-shielding layers 110. In some embodiments, the bump 130 includes silicon dioxide or the like. In some embodiments, the plurality of bumps 130 are arranged only on a portion of the light-shielding layers 110. In some embodiments, the bump 130 partially covers the end portion 122 of the first electrode layer 120. The bumps 130 may have different shapes. In some embodiments, the bump 130 has a bottom surface 131 in direct contact with the top surface 112 of the light-shielding layer 110 and a curved top surface 132 in contact with the light-emitting array 200. In some embodiments, the bump 130 has a substantially trapezoidal cross-section. In some embodiments, the bump 130 has a substantially rectangular cross-section. The bump 130 is arranged above the light-shielding layer 110. Each bump 130 fills a gap between two adjacent first electrode layers 120. The end portion 122 of each first electrode layer 120 is partially covered by the bump 130. The bump 130 may include a photosensitive material. In FIG. 2, in a lateral direction, a width of the light-shielding layer 110 is greater than a width of the bump 130.

In some embodiments, a width W5 of the bottom surface 131 of each bump 130 is substantially equal to, greater than, or less than a width W6 of the top surface 132 of each bump 130. In some embodiments, the width W5 of the bottom surface 131 of each bump 130 is greater than the width W6 of the top surface 132 of each bump 130. In some embodiments, a ratio of the width W5 of the bottom surface 131 of each bump 130 to the width W6 of the top surface 132 of each bump 130 is about 1:1 to about 10:1. In some embodiments, the ratio of the width W5 of the bottom surface 131 of each bump 130 to the width W6 of the top surface 132 of each bump 130 is about 1:1 to about 7:1. In some embodiments, the ratio of the width W5 of the bottom surface 131 of each bump 130 to the width W6 of the top surface 132 of each bump 130 is about 1:1 to about 3:1.

In some embodiments, the width W5 of the bottom surface 131 of each bump 130 is substantially equal to, greater than, or less than the width W2 of the top surface 112 of the light-shielding layer 110. In some embodiments, the width W5 of the bottom surface 131 of the bump 130 is less than the width W2 of the top surface 112 of the light-shielding layer 110. In some embodiments, a ratio of the width W5 of the bottom surface 131 of the bump 130 to the width W2 of the top surface 112 of the light-shielding layer 110 is about 1:1 to about 1:5. In some embodiments, the ratio of the width W5 of the bottom surface 131 of each bump 130 to the width W2 of the top surface 112 of the light-shielding layer 110 is about 9:10 to about 3:10. In some embodiments, the ratio of the width W5 of the bottom surface 131 of each bump 130 to the width W2 of the top surface 112 of the light-shielding layer 110 is about 4:5 to about 2:5.

In some embodiments, the width W6 of the top surface 132 of the bump 130 is less than the width W2 of the top surface 112 of the light-shielding layer 110. In some embodiments, a ratio of the width W6 of the top surface 132 of the bump 130 to the width W2 of the top surface 112 of the light-shielding layer 110 is about 1:1 to about 1:10. In some embodiments, the ratio of the width W6 of the top surface 132 of the bump 130 to the width W2 of the top surface 112 of the light-shielding layer 110 is about 1:3 to about 1:7. In some embodiments, the ratio of the width W6 of the top surface 132 of the bump 130 to the width W2 of the top surface 112 of the light-shielding layer 110 is about 1:4 to about 1:6.

In some embodiments, a thickness H3 of the bump 130 is substantially equal to, less than, or greater than the thickness H1 of the light-shielding layer 110. In some embodiments, the thickness H3 of the bump 130 is greater than the thickness H1 of the light-shielding layer 110. In some embodiments, a ratio of the thickness H3 of the bump 130 to the thickness H1 of the light-shielding layer 110 is about 10:1 to about 1:1. In some embodiments, the ratio of the thickness H3 of the bump 130 to the thickness H1 of the light-shielding layer 110 is about 7:1 to about 2:1. In some embodiments, the ratio of the thickness H3 of the bump 130 to the thickness H1 of the light-shielding layer 110 is about 5:1 to about 3:1.

In some embodiments, the thickness H3 of the bump 130 is substantially equal to, less than, or greater than the thickness H2 of the central portion 121 of the first electrode layer 120. In some embodiments, the thickness H3 of the bump 130 is greater than the thickness H2 of the central portion 121 of the first electrode layer 120. In some embodiments, a ratio of the thickness H3 of the bump 130 to the thickness H2 of the central portion 121 of the first electrode layer 120 is from about 10:1 to about 1:1. In some embodiments, the ratio of the thickness H3 of the bump 130 to the thickness H2 of the central portion 121 of the first electrode layer 120 is from about 7:1 to about 2:1. In some embodiments, the ratio of the thickness H3 of the bump 130 to the thickness H2 of the central portion 121 of the first electrode layer 120 is from about 5:1 to about 3:1.

In some embodiments, the bump 130 has an edge covering the end portion 122 of the first electrode layer 120. The sidewall 113 of the light-shielding layer 110 may be aligned or may not be aligned with the edge of the bump 130. As shown in FIG. 2, the sidewall 113 of the light-shielding layer 110 is not aligned with the edge of the bump 130. There is an offset between the edge of the bump 130 and the sidewall 113 of the light-shielding layer 110. A percentage of the offset relative to the width of the light-shielding layer 110 may be greater than or equal to 10%. The percentage of the offset relative to the width of the light-shielding layer 110 may be greater than or equal to 20%. The percentage of the offset relative to the width of the light-shielding layer 110 may be greater than or equal to 30%. The percentage of the offset relative to the width of the light-shielding layer 110 may be greater than or equal to 40%.

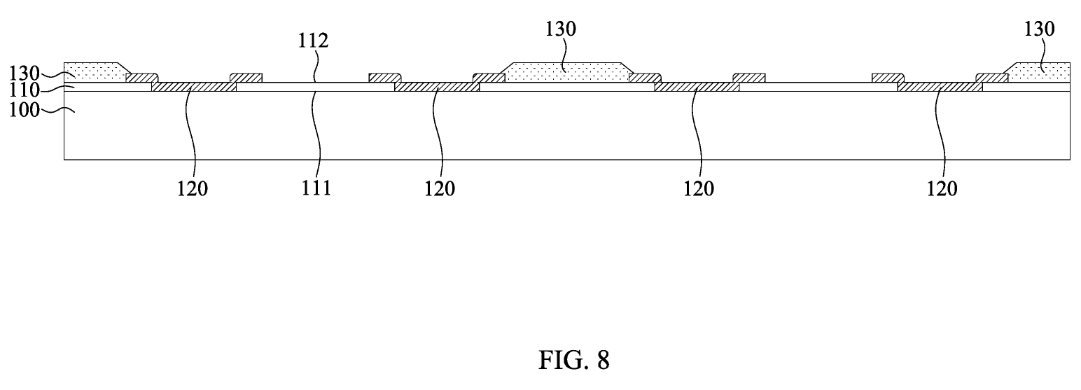

In some embodiments, the light-emitting assembly 10 may not include the bump 130. Alternatively, in some embodiments, as shown in FIG. 8, the light-emitting assembly 10 is provided with the bump 130 on a portion of the light-shielding layer 110, so that a portion of the edge of the end portion 122 of the first electrode layer 120 is covered by the bump 130, a portion of the top portion 112 of the light-shielding layer 110 is exposed between the end portions 122 of adjacent first electrode layer 120, and is then covered by the organic light-emitting array 200, such that the organic light-emitting array 200 is in contact with a portion of the light-shielding layer 110.

In some embodiments, the organic light-emitting array 200 comprises an organic layer 210 (also referred to as an emitting layer) and a second electrode layer 220 on the organic layer 210.

In some embodiments, the organic layer 210 comprises one or more layers of organic light-emitting materials. The organic light-emitting materials comprise an electron transport layer (ETL), an electron injection layer (EIL), an emission layer (EM), a hole blocking layer (HBL), a hole injection layer (HIL), a hole transport layer (HTL), or any combination thereof. In some embodiments, the organic layer 210 comprises a first carrier transport layer 212 disposed over the bump 130 and the first electrode layer 120, a second carrier transport layer 213 disposed over the first carrier transport layer 212, and an organic emission layer 214 disposed over the second carrier transport layer 213. In some embodiments, the organic layer 210 further comprises a carrier injection layer 211 arranged between the first electrode layer 120 and the first carrier transport layer 212. In some embodiments, the organic layer 210 further comprises an organic carrier transport layer 215 disposed over the organic emission layer 214. In some embodiments, the carrier injection layer 211 may be a hole injection layer, the first carrier transport layer 212 may be a first hole transport layer, the second carrier transport layer 213 may be a second hole transport layer, and the organic carrier transport layer 215 may be an electron transport layer.

In some embodiments, the second electrode layer 220 is disposed over the organic layer 210. In some embodiments, the first electrode layer 120 is an anode and the second electrode layer 220 is a cathode. In some embodiments, the second electrode layer 220 comprises a transparent conductive material. The second electrode layer 220 is patterned so as to cover only effective light-emitting regions of the respective organic light-emitting units 200A and 200B. In some embodiments, the second electrode layer 220 is in contact with the organic layer 210. The second electrode layer 220 may be a continuous film, as shown in FIG. 2, and disposed over the organic layer 210. In other words, the second electrode layer 220 serves as a common electrode for several organic light-emitting units 200A and 200B. In some embodiments, the second electrode layer 220 serves as a common electrode for all of the organic light-emitting units 200A and 200B in the light-emitting assembly.

In some embodiments, the second electrode layer 220 may have a thickness of about 80 Å to about 500 Å. In some embodiments, the second electrode layer 220 may have a thickness of about 80 Å to about 150 Å. In some embodiments, the second electrode layer 220 may have a thickness of about 150 Å to about 200 Å. In some embodiments, the second electrode layer 220 may have a thickness of about 200 Å to about 300 Å. In some embodiments, the second electrode layer 220 may have a thickness of about 300 Å to about 400 Å. In some embodiments, the second electrode layer 220 may have a thickness of about 400 Å to about 500 Å.

In some embodiments, the second electrode layer 220 may be a cathode. The second electrode layer 220 may be formed of a metal material, such as Ag, Mg, etc. In some embodiments, the second electrode layer 220 comprises ITO (indium tin oxide) or IZO (indium zinc oxide).

According to some embodiments of the present disclosure, in the light-emitting assembly, the light-shielding layer 110 may serve as a pixel defining layer (PDL), and therefore the bump 130 may be disposed as needed. Since the light-shielding layer 110 is disposed directly adjoining and between the plurality of first electrode layers 120, it is possible to define the light-emitting region, effectively reduce halo issues of the light-emitting pattern, and improve the contrast of the light-emitting pattern, such that a boundary of the light-emitting pattern becomes clearer, thereby enabling a light-emitting pattern having a fine pattern design and high contrast.

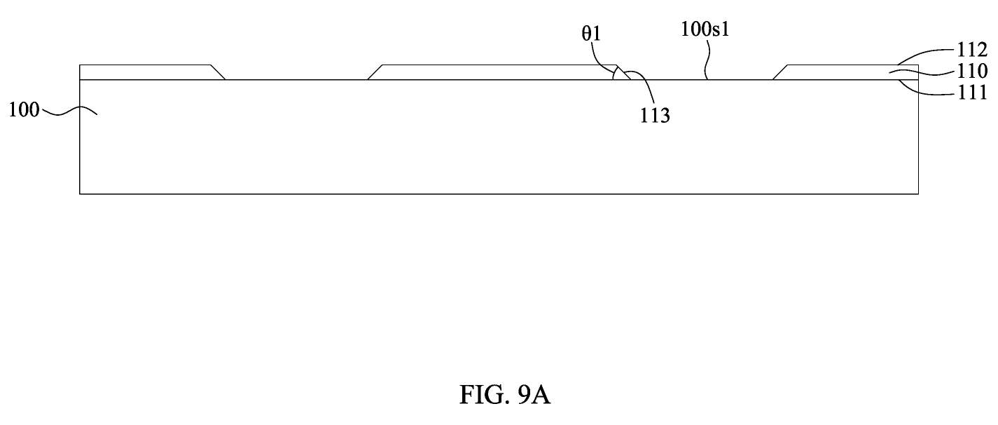

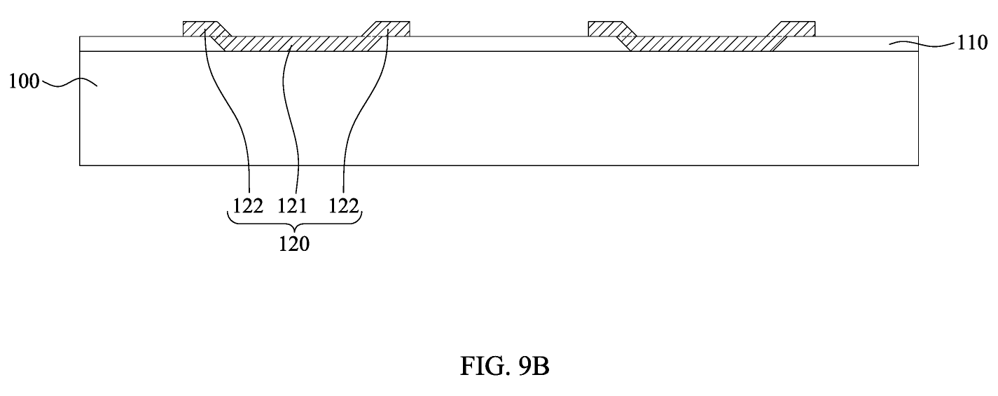

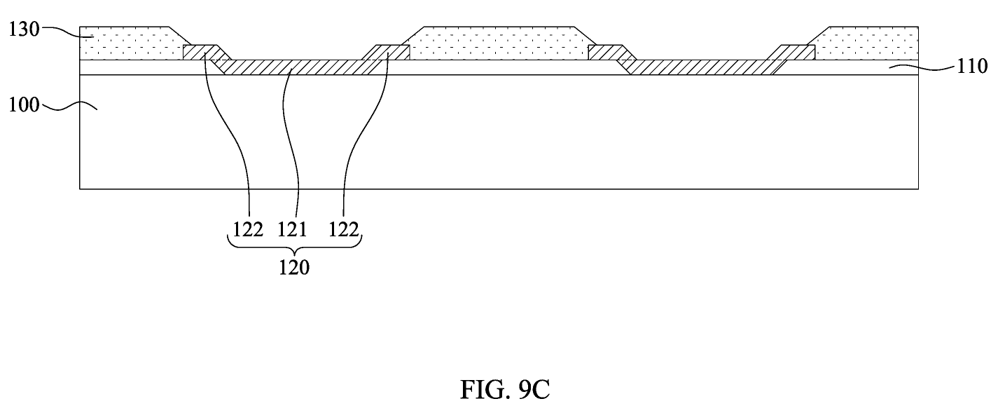

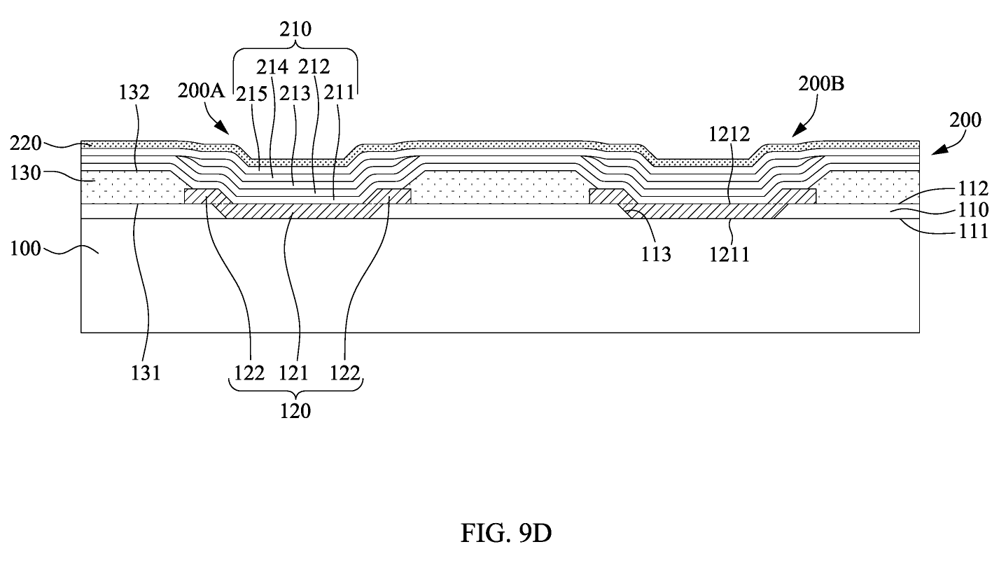

FIGS. 9A-9D illustrate different stages of a manufacturing process of the light-emitting assembly 10 according to an embodiment.

In FIG. 9A, a substrate 100 having an upper surface 100s1 is provided, and a plurality of light-shielding layers 110 are formed at intervals on the first surface 100s1 of the substrate 100. The pattern of the light-shielding layers 110 is designed according to the pixel arrangement, and the patterned light-shielding layers 110 may be referred to as a pixel defining layer (PDL). A bottom surface 111 of each light-shielding layer 110 is in direct contact with the upper surface 100s1 of the substrate 100. An angle θ1 between a sidewall 113 of the light-shielding layer 110 and the first surface 100s1 of the substrate 100 is greater than 0 degree and up to about 90 degrees. In some embodiments, the angle θ1 between the sidewall 113 of the light-shielding layer 110 and the first surface 100s1 of the substrate 100 is about 20 degrees to about 70 degrees. In some embodiments, the angle θ1 between the sidewall 113 of the light-shielding layer 110 and the first surface 100s1 of the substrate 100 is about 35 degrees to about 60 degrees. In some embodiments, the plurality of light-shielding layers 110 may be formed on the first surface 100s1 of the substrate 100 by any of vapor deposition, sputtering, atomic layer deposition, thermal evaporation, coating, or spray coating. Each of the plurality of light-shielding layers 110 may be a single layer or multiple layers, and each layer in the multilayer structure may be selectively formed by any of vapor deposition, sputtering, atomic layer deposition, thermal evaporation, coating, or spray coating. In some embodiments, one or more light-absorbing layers 110a may be formed on the first surface 100s1 of the substrate 100 by any of vapor deposition, sputtering, atomic layer deposition, thermal evaporation, coating, or spray coating, and then a bonding layer 110b may be formed on a surface of the one or more light-absorbing layers 110a by any of vapor deposition, sputtering, atomic layer deposition, thermal evaporation, coating, or spray coating (as shown in FIG. 4). In some embodiments, the light-absorbing layer 110a includes a light-absorbing material, including but not limited to metal, metal oxide, carbon black materials, such as carbon black nanoparticles, conductive fibers including carbon black, or the like, and the bonding layer 110b comprises silicon dioxide.

In FIG. 9B, a first electrode layer 120 is formed between the plurality of light-shielding layers 110. The first electrode layer 120 may be formed on the upper surface 100s1 of the substrate 100 by any of vapor deposition, sputtering, atomic layer deposition, thermal evaporation, coating, or spray coating. Each first electrode layer 120 is configured to be electrically connected to the substrate 100. Each first electrode layer 120 includes a central portion 121 in direct contact with the upper surface 100s1 of the substrate 100 and an end portion 122 disposed across the sidewall 113 and a part of the top surface 112 of the adjacent light-shielding layer 110. In some embodiments, a shape of the central portion 121 of the first electrode layer 120 may vary according to a shape of the sidewall 113 of the light-shielding layer 110.

In FIG. 9C, a bump 130 is formed on the top surface 112 of the light-shielding layer 110, and the bump 130 covers the edge of the end portion 122 of the first electrode layer 120. The bump 130 may be formed on the top surface 112 of the light-shielding layer 110 by any of vapor deposition, sputtering, atomic layer deposition, thermal evaporation, coating, or spray coating. A material for forming the bump 130 may be the same as or compatible with a material of the bonding layer 110b serving as the top layer of the light-shielding layer 110, so that better adhesion is achieved between the bump 130 and the light-shielding layer 110.

After forming the bump 130, a cleaning operation is performed to clean exposed surfaces of the bump 130 and the first electrode layer 120. In one embodiment, during the cleaning operation, deionized water is heated to a temperature between 30° C and 80° C. After the temperature of the deionized water is raised to a predetermined temperature, the deionized water is directed onto the exposed surfaces of the bump 130 and the first electrode layer 120.

In some embodiments, ultrasonic waves are used during the cleaning operation. The ultrasonic waves are introduced into a cleaning agent (for example, water or isopropyl alcohol (IPA), etc.). In some embodiments, carbon dioxide is introduced into the cleaning agent. After the cleaning operation, the cleaning agent is removed from the exposed surfaces by a heating operation. During the heating operation, the substrate 100 and the bump 130 may be heated to a temperature between 80° C and 110° C. In some examples, compressed air is directed onto the exposed surfaces to help remove residues of the cleaning agent while heating.

After the heating operation, the exposed surfaces may be treated with O₂, N₂, or Ar plasma. The plasma may be used to roughen the exposed surfaces. In some embodiments, ozone is used to adjust the surface condition of the exposed surfaces.

In FIG. 9D, a carrier injection layer 211 is disposed on the exposed surfaces of the bump 130 and the first electrode layer 120 (and/or on the exposed surface of the light-shielding layer 110 where no bump 130 is formed). The carrier injection layer 211 continuously lines the exposed surfaces. More specifically, the exposed surface of each first electrode layer 120 is configured as the effective light-emitting area of a light-emitting unit (i.e., a pixel). In this embodiment, all light-emitting units use the carrier injection layer 211. In some embodiments, the carrier injection layer 211 is used for hole injection. In some embodiments, the carrier injection layer 211 is used for electron injection. The carrier injection layer 211 continuously covers the exposed surfaces of the plurality of bumps 130 and the first electrode layers 120. In some embodiments, the carrier injection layer 211 is in contact with the bumps 130. In one embodiment, the carrier injection layer 211 is in contact with the first electrode layer 120. In some embodiments, the carrier injection layer 211 is in contact with the light-shielding layer 110 where no bump 130 is formed. In some embodiments, the carrier injection layer 211 is organic.

A first carrier transport layer 212 is provided on the exposed surfaces of the bump 130 and the first electrode layer 120 (and/or on the exposed surface of the light-shielding layer 110 where no bump 130 is formed). The carrier injection layer 211 is disposed beneath the first carrier transport layer 212. The first carrier transport layer 212 continuously lines the carrier injection layer 211. In this embodiment, all light-emitting units use the first carrier transport layer 212. In some embodiments, the first carrier transport layer 212 is used for hole injection. In some embodiments, the first carrier transport layer 212 is used for electron injection. The first carrier transport layer 212 continuously covers the plurality of bumps 130 and the first electrode layer 120 (or the light-shielding layer where no bump 130 is formed). Optionally, the first carrier transport layer 212 is in contact with the carrier injection layer 211. In some embodiments, the first carrier transport layer 212 is organic.

A second carrier transport layer 213 is disposed above the first carrier transport layer 212. The second carrier transport layer 213 continuously lines the first carrier transport layer 212. In this embodiment, all light-emitting units use the second carrier transport layer 213.

An organic emission layer 214 is disposed on the exposed surfaces of the bump 130 and the first electrode layer 120 (and/or on the exposed surface of the light-shielding layer 110 where no bump 130 is formed). The organic emission layer 214 covers the second carrier transport layer 213. The organic emission layer 214 completely covers the exposed second carrier transport layer 213. The organic emission layer 214 is configured to emit a first color.

An organic carrier transport layer 215 is disposed on the organic emission layer 214. The organic carrier transport layer 215 may be a hole or electron transport layer. In some embodiments, the organic carrier transport layer 215 and the carrier transport layers 212 and 213 are respectively configured to have opposite polarities.

A second electrode layer 220 is disposed on the organic carrier transport layer 215. The second electrode layer 220 covers the organic carrier transport layer 215. The second electrode layer 220 may be a metal material, such as Ag, Mg, etc. In some embodiments, the second electrode layer 220 comprises ITO (indium tin oxide) or IZO (indium zinc oxide). In some embodiments, each light-emitting unit (i.e., pixel) may have an independent second electrode layer 220.

The operations shown in FIGS. 9A-9D may be repeatedly performed to form light-emitting units of different colors.

This application allows the pattern to be adjusted into the desired shape according to actual needs.

The foregoing content outlines features of some embodiments, so those skilled in the art can better understand various aspects of the present disclosure. Those skilled in the art should understand that the present disclosure can be easily used as a basis to design or modify other processes and structures to achieve the same purposes and/or advantages as the embodiments described in this application. Those skilled in the art should also understand that such equivalent structures do not depart from the spirit and scope of the present disclosure, and that various changes, substitutions, and replacements can be made without departing from the spirit and scope of the present disclosure.

What is claimed is:

1. A light-emitting element, comprising:
a substrate;
a plurality of light-shielding layers disposed at intervals over a first surface of the substrate;
a plurality of first electrode layers disposed over the first surface of the substrate, each of the plurality of first electrode layers disposed between the two adjacent light-shielding layers;
a light-emitting layer covering the plurality of first electrode layers; and
a second electrode layer covering the light-emitting layer.

2. The light-emitting element of claim 1, wherein each of the plurality of first electrode layers includes a central portion and an end portion extending from a side of the central portion, the central portion is disposed between the two adjacent light-shielding layers, and the end portion is disposed across a sidewall and a part of a top surface of the adjacent light-shielding layer.

3. The light-emitting element of claim 2, wherein an angle between a sidewall of the end portion of the first electrode layer and the top surface of the light-shielding layer is greater than 0 degree and up to about 90 degrees.

4. The light-emitting element of claim 2, wherein a thickness of the central portion of the first electrode layer is substantially equal to or less than a thickness of the light-shielding layer.

5. The light-emitting element of claim 1, further comprising a plurality of bumps arranged over the plurality of light-shielding layers, and the light-emitting layer covering the plurality of bumps.

6. The light-emitting element of claim 2, further comprising a plurality of bumps arranged over the plurality of light-shielding layers, the plurality of bumps partially covering the end portion of the first electrode layer, and the light-emitting layer covering the plurality of bumps.

7. The light-emitting element of claim 1, wherein a thickness of the central portion of the first electrode layer is substantially equal to a thickness of the end portion.

8. The light-emitting element of claim 1, wherein a width of a top surface of each of the plurality of light-shielding layers is substantially equal to or less than a width of a bottom portion thereof.

9. The light-emitting element of claim 1, wherein an angle between a sidewall of each of the plurality of light-shielding layers and the first surface of the substrate is greater than 0 degree and up to about 90 degrees.

10. The light-emitting element of claim 1, wherein the plurality of light-shielding layers includes a light-absorbing layer disposed over the first surface of the substrate and a bonding layer covering the light-absorbing layer.

11. A method of manufacturing a light-emitting element, comprising:
providing a substrate;
forming a plurality of light-shielding layers at intervals over a first surface of the substrate;
forming a plurality of first electrode layers over the substrate, including forming a central portion between the light-shielding layers and an end portion extending from a side of the central portion and disposed across a sidewall and a part of a top surface of the adjacent light-shielding layer;
forming a light-emitting layer over the plurality of first electrode layers; and
forming a second electrode layer over the light-emitting layer.

12. The method of claim 11, wherein, prior to forming the light-emitting layer, a plurality of bumps are formed over the plurality of light-shielding layers and partially cover the end portion of the first electrode layer; the light-emitting layer is formed over the plurality of first electrode layers and the plurality of light-shielding layers.

13. The method of claim 11, wherein an angle between a sidewall of the end portion of the first electrode layer and a top surface of the light-shielding layer is greater than 0 degree and up to about 90 degrees.

14. The method of claim 11, wherein an angle between a sidewall of each of the plurality of light-shielding layers and the first surface of the substrate is greater than 0 degree and up to about 90 degrees.

15. The method of claim 12, wherein a thickness of the central portion of the first electrode layer is substantially equal to or less than a thickness of the light-shielding layer, and the thickness of the central portion of the first electrode layer is substantially equal to a thickness of the end portion.
